(19) United States
(12) Patent Application Publication
(10) Pub. No.: US 2025/0383262 A1
(43) Pub. Date: Dec. 18, 2025

(54) METHODS AND APPARATUS FOR LIFT PIN ERROR DETECTION

(71) Applicant: ASM IP Holding B.V., Almere (NL)

(72) Inventors: Matthew Ricketts, Scottsdale, AZ (US); Hang Zhang, Tempe, AZ (US); Shubham Garg, Gilbert, AZ (US); Todd Robert Dunn, Cave Creek, AZ (US); Roland Ashley Fernandes, Tempe, AZ (US)

(21) Appl. No.: 19/237,216

(22) Filed: Jun. 13, 2025

Related U.S. Application Data
(60) Provisional application No. 63/661,182, filed on Jun. 18, 2024.

(51) Int. Cl. G01M 13/027; G01M 3/28; H01L 21/687

(52) U.S. Cl. CPC G01M 13/027; G01M 3/2815; H01L 21/68742

(57) ABSTRACT

Various embodiments of the present technology may provide an apparatus having a susceptor with a plurality of gas channels therethrough and a plurality of pressure sensors coupled to the gas channels. The apparatus may further include a controller in communication with the plurality of sensors and configured to detect a change in pressure or flow rate within the plurality of channels, determine a failure of at least one of the plurality of lift pins based on the detected change in pressure or flow rate, and generate an error signal based on the determined failure.

### CROSS-REFERENCE TO RELATED APPLICATIONS

This application is a nonprovisional of, and claims priority to and the benefit of, U.S. Provisional Patent Application No. 63/661,182, filed Jun. 18, 2024 and entitled “METHODS AND APPARATUS FOR LIFT PIN ERROR DETECTION,” which is hereby incorporated by reference herein.

### FIELD OF INVENTION

The present disclosure generally relates to a method and apparatus for lift pin error detection. More particularly, the present disclosure relates to a susceptor having a plurality of gas channels within the wafer pocket and a plurality of pressure sensors coupled to the plurality of gas channels. The pressure or flow through the pressure sensor may correspond to a lift pin error.

### BACKGROUND OF THE TECHNOLOGY

Lift pins within the susceptor may experience failures or errors, such as sticking within the lift pin through-hole or breaking. Conventional systems do not have a method or mechanism to detect the lift pin error in a timely manner.

### SUMMARY OF THE INVENTION

Various embodiments of the present technology may provide an apparatus having a susceptor with a plurality of gas channels therethrough and a plurality of pressure sensors coupled to the gas channels. The apparatus may further include a controller in communication with the plurality of sensors and configured to detect a change in pressure or flow rate within the plurality of channels, determine a failure of at least one of the plurality of lift pins based on the detected change in pressure or flow rate, and generate an error signal based on the determined failure.

According to one aspect, an apparatus comprises: a susceptor comprising: a first surface and a second surface that is parallel to the first surface; a recessed region within the first surface that is sized to accept a wafer; a first plurality of through-holes extending from the first surface to the second surface and disposed within the recessed region; a plurality of lift pins disposed within the first plurality of through-holes; and a plurality of gas channels having an opening at the first surface and within the recessed region; a plurality of pressure sensors fluidly coupled to the plurality of gas channels; and a controller in communication with the plurality of sensors and configured to: detect a change in pressure or flow rate within the plurality of gas channels; determine a failure of at least one of the plurality of lift pins based on the detected change in pressure or flow rate; and generate an error signal based on the determined failure.

In one embodiment, the openings of at least two gas channels from the plurality of gas channels are directly adjacent to each through-hole from the plurality of through-holes.

In one embodiment, the plurality of gas channels comprises 6 channels.

In one embodiment, the openings of the plurality of gas channels are disposed 120 degrees from each other.

In one embodiment, the openings of the plurality of gas channels are arranged adjacent to and radially inward from an outer edge of the recessed region.

In one embodiment, the plurality of gas channels contains, at most, 3 channels.

In one embodiment, the apparatus further comprises a plurality of gas ports disposed at the first surface and coupled to an inert gas supply.

In one embodiment, the plurality of gas ports are arranged radially outward from the recessed region.

In one embodiment, the plurality of gas ports are arranged adjacent to the openings of the plurality of gas channels.

In one embodiment, the apparatus further comprises a pump coupled to the plurality of gas ports and configured to apply a suction force at the first surface.

In one embodiment, the apparatus further comprises a pump coupled to the plurality of gas channels and configured to evacuate air from the plurality of gas channels.

In one embodiment, determining a failure of at least one lift pin comprises detecting an increase in pressure or flow rate.

In another aspect, an apparatus comprises: a susceptor comprising: a first surface and a second surface that is parallel to the first surface; an interior, circular region on the first surface that is configured to support a wafer; a first plurality of through-holes extending from the first surface to the second surface and disposed within the interior region; a plurality of lift pins disposed within the first plurality of through-holes; and a plurality of gas channels having an opening at the first surface and within the interior region, wherein the plurality of gas channels comprises at least 3 gas channels and wherein the openings of the plurality of gas channels are arranged adjacent to an outer edge of the interior region, and wherein the openings of the plurality of gas channels are disposed 120 degrees from each other; a plurality of pressure sensors fluidly coupled to the plurality of gas channels; a controller in communication with the plurality of sensors and configured to: detect a change in pressure or gas flow rate within at least one channel from the plurality of gas channels; determine a failure of at least one lift pin from the plurality of lift pins based on the detected change in pressure or flow rate; and generate an error signal based on the determined failure.

In one embodiment, the apparatus further comprises a plurality of gas ports disposed at the first surface and coupled to an inert gas supply, wherein the plurality of gas ports are arranged radially outward from the interior region.

In one embodiment, the plurality of gas ports are arranged adjacent to the openings of the plurality of gas channels and spaced 120 degrees from each other.

In one embodiment, the apparatus further comprises a pump fluidly coupled to the plurality of gas ports and configured to facilitate air flow away from the first surface.

In one embodiment, determining a failure of at least one lift pin comprises detecting an increase in pressure or gas flow rate.

In yet another aspect, a system, comprises: a susceptor comprising: a first surface and a second surface that is parallel to the first surface; an interior, circular region on the first surface that is configured to support a wafer; a first plurality of through-holes extending from the first surface to the second surface and disposed within the recessed region; a plurality of lift pins disposed within the first plurality of through-holes; and a plurality of gas channels having an opening at the first surface and within the interior region, wherein plurality of gas channels comprises at least 3 channels; a plurality of pressure sensors fluidly coupled to the plurality of gas channels; a controller in communication with the plurality of sensors and configured to: detect a change in pressure or gas flow rate within the plurality of gas channels; determine a failure of at least one lift pin from the plurality of lift pins based on the detected increase in pressure; and generate an error signal based on the determined failure; and a pump coupled to the plurality of gas channels and configured to evacuate air from the plurality of gas channels.

In one embodiment, each pressure sensor from the plurality of pressure sensors comprises a pressure transducer and the pump is downstream from the plurality of sensors.

In one embodiment, each pressure sensor from the plurality of pressure sensors comprises a pressure flow controller and each pressure flow controller is fluidly coupled to an inert gas source and configured to receive an inert gas from the inert gas source.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 is a schematic diagram of a system in accordance with embodiments of the present technology;

FIG. 2A is a cross-sectional view of a reactor with a susceptor in a first position in accordance with embodiments of the present technology;

FIG. 2B is a cross-sectional view of a reactor with a susceptor in a second position in accordance with embodiments of the present technology;

FIGS. 3A-3B is a cross-section view of a susceptor in accordance with embodiments of the present technology;

FIG. 4 is a top view of the susceptor in accordance with embodiments of the present technology; and

FIGS. 5A-5B is a cross-sectional view of a portion of the susceptor in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, controllers, reaction chambers, vessels, and susceptors.

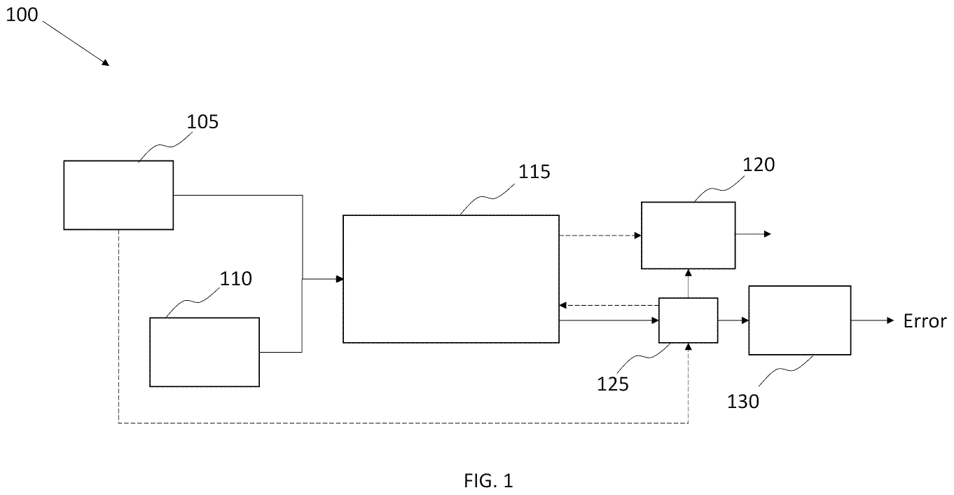

Referring to FIGS. 1-3, an exemplary system 100 may comprise a reactor 115 configured to perform processing on an object to be processed, such as a substrate 215 (e.g., a wafer). For example, the reactor 115 may be configured to perform heating, deposition, etching, polishing, ion implantation, and/or other processing on the object to be processed. In some embodiments, the reactor 115 may be configured to perform a movement function, a vacuum sealing function, an exhaust function. In some embodiments, the reactor 115 may perform an atomic layer deposition (ALD) process or a chemical vapor deposition (CVD) process. The reactor 115 may be fluidly coupled to and configured to receive an inert gas (such as argon) from an inert gas source 105. For example, the reactor 115 may be coupled to the inert gas source 105 with gas lines (not shown) and valves (not shown).

In various embodiments, the reactor 115 may also be fluidly coupled to and configured receive a chemical from a vessel 110. The vessel 110 may comprise any container suitable for holding or otherwise containing a chemical. The vessel 110 may be configured to hold a solid or a liquid chemical, and may further be configured to transform the solid or liquid into a vapor.

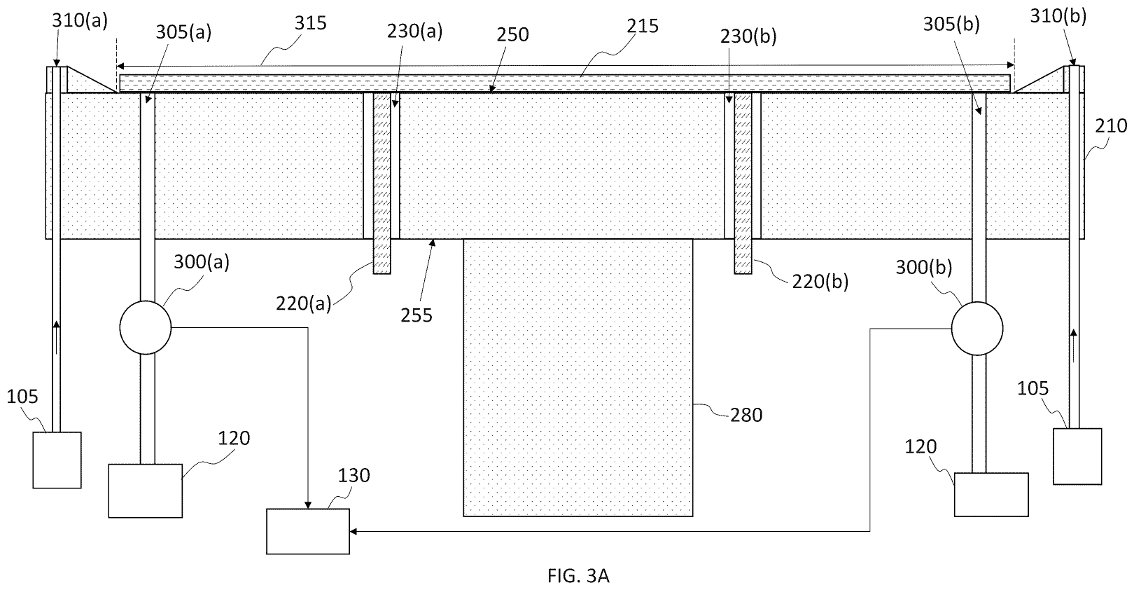

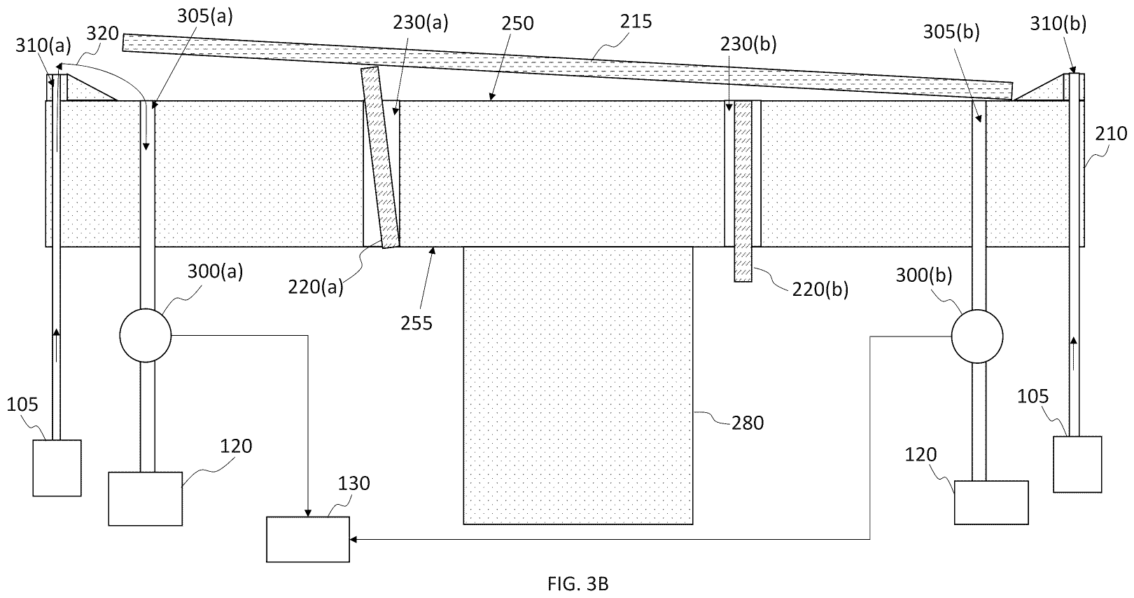

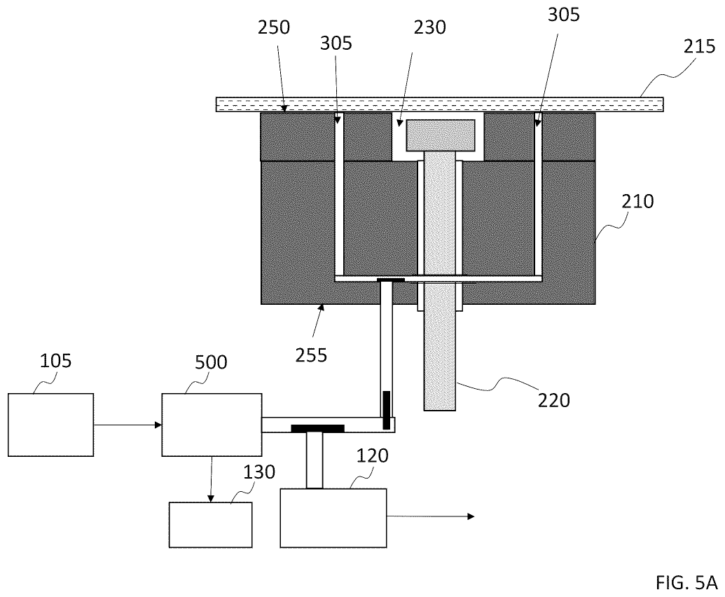

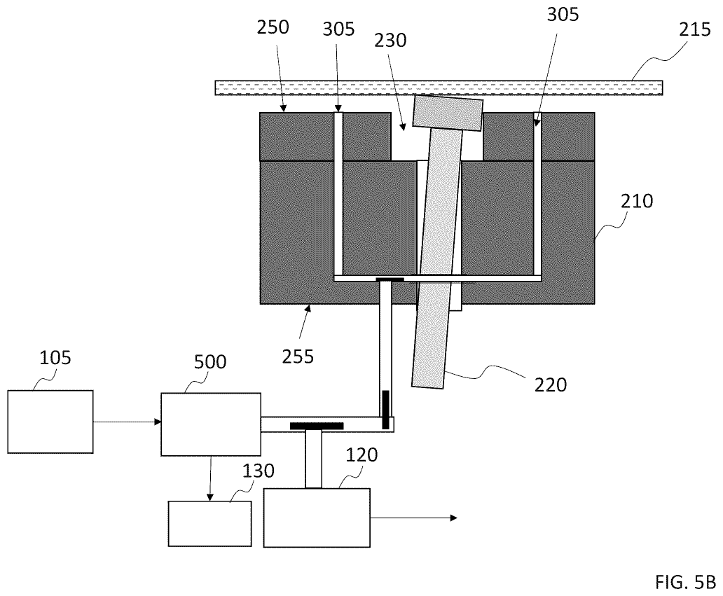

In various embodiments, the system 100 may further comprise a sensor system 125 configured to monitor or otherwise detect various parameters within the system 100 and/or the reactor 115. In an exemplary embodiment, the sensor system 125 may comprise a plurality of pressure sensors configured to measure and/or control pressure and/or flow rate of a gas. For example, the sensor system 125 may comprise a pressure transducer 300 (FIG. 3A) and/or or a pressure flow controller 500 (FIG. 5). In various embodiments, all or part of the sensor system 125 may be disposed outside the reactor 115. In addition or alternatively, all or part of the sensor system 125 may be disposed inside the reactor 115.

In various embodiments, the system 100 may further comprise a controller 130 in communication with the sensor system 125. For example, the controller 130 may receive output signals from the sensor system 125 and/or transmit control signals to the sensor system 125. The controller 130 may comprise any suitable device or system for processing and analyzing data and/or signals (such as output signals from the pressure sensors).

In various embodiments, the system 100 may further comprise an exhaust system 120 configured to facilitate gas evacuation from the reactor 115. In various embodiments, the exhaust system 120 may comprise a pump (not shown) to remove gas from features of the reactor 115 and/or apply a suction force.

In an exemplary embodiment, the reactor 115 may comprise a reaction chamber 205 comprising a reaction space 235 above and/or around the substrate 215. For example, the reaction chamber 205 may comprise sidewalls and a bottom coupled to the sidewalls that form an enclosed volume.

In various embodiments, the reactor 115 may further comprise a gas distribution system 200 for delivering a vapor from the vessel 110 into the reaction chamber 205 and the reaction space 235. In an exemplary embodiment, the gas distribution system 200 is arranged above the susceptor 210.

In various embodiments, the gas distribution system 200 may be arranged adjacent to the reaction chamber 205. For example, the gas distribution system 200 may be arranged on the sidewalls of the reaction chamber 205, opposite the bottom of the reaction chamber 205. In some embodiments, the gas distribution system 200 may be fastened to the sidewalls, however, in other cases, the gas distribution system 200 may merely rest on the sidewalls of the reaction chamber 205. In various embodiments, the gas distribution system 200 together with the reaction chamber 205 sidewalls form an enclosed space, including the reaction space 235.

In various embodiments, the reaction chamber 205 may further comprise lift pin pads 240 disposed at or near the bottom of the reaction chamber 205.

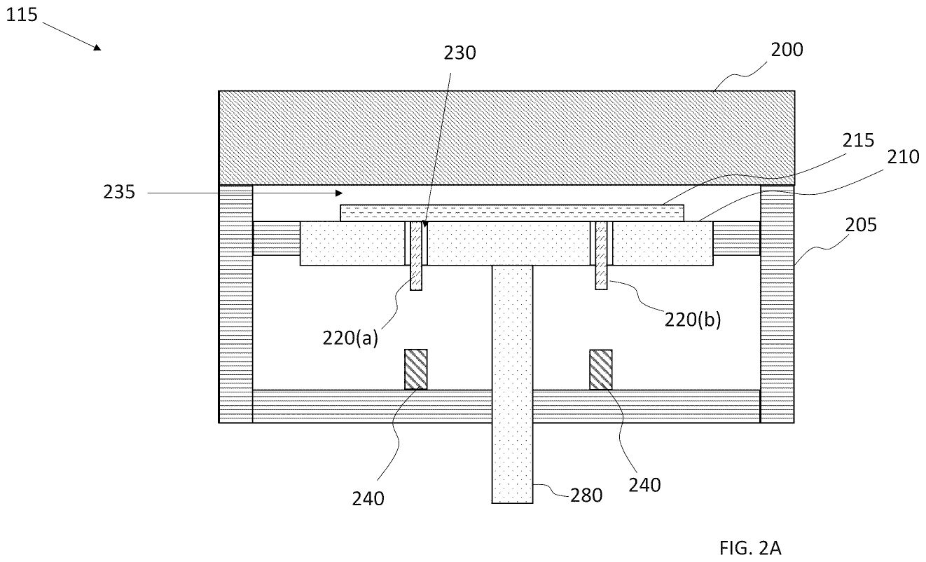

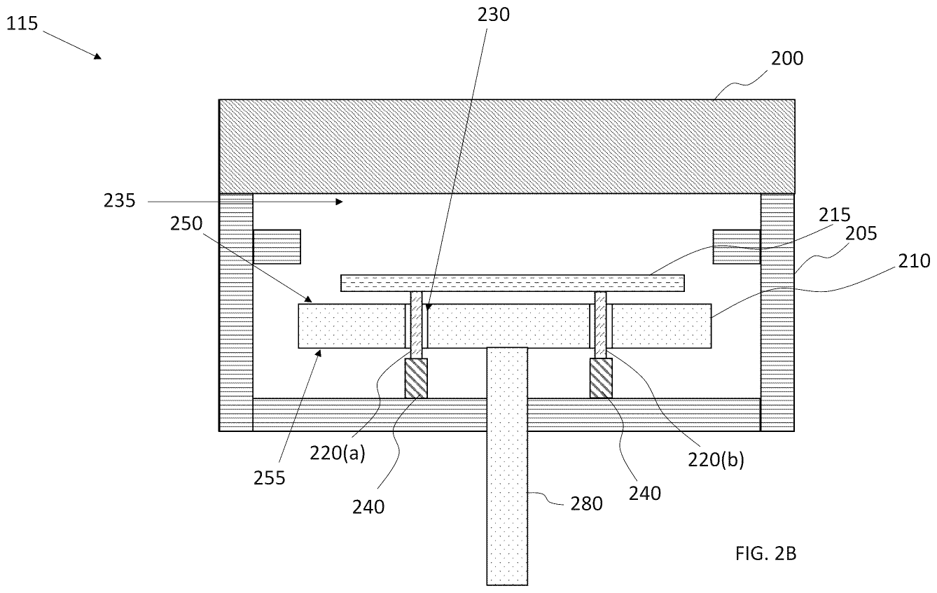

In various embodiments, the reactor 115 may further comprise a substrate mounting unit disposed within the reaction chamber 205 of the reactor 115. The substrate mounting unit may comprise a susceptor 210 for supporting the substrate 215 and a heater (not shown) for heating the substrate 215 supported by the susceptor 210. The heater may be embedded within the susceptor 210. The substrate mounting unit may further comprise a pedestal 280 to support the susceptor 210. For loading/unloading of the substrate 215, the substrate mounting unit may be configured to be vertically movable (up and down) by being connected to a driving unit (not shown). For example, as illustrated in FIG. 2A, the driving unit may place the susceptor 210 in a first position (also referred to as a processing position) to deposit film or otherwise perform processing on the substrate 215. In the first position, the susceptor 210 may be disposed in or adjacent to the reaction space 235. For example, the susceptor 210 may be arranged to position the substrate 215 in the reaction space 235. As illustrated in FIG. 2B, the driving unit may place the susceptor 210 in a second position (also referred to as an unloading/loading position) were the substrate is loaded onto or unloaded from the susceptor 210.

In various embodiments, the susceptor 210 may comprise a first surface 250 and an opposing second surface 255. The first surface 250 may comprise a central region 315 defined by an area on the first surface 250 that receives and makes direct contact with the substrate 215. In some embodiments, the central region 315 is recessed and forms a pocket enclosed by an elevated surface (e.g., as illustrated in FIGS. 3A-3B). In such embodiments, the substrate 215 is sized to be placed within the central region 315 and directly on the first surface 250.

In various embodiments, the susceptor 210 may further comprise a plurality of through-holes 230, such as a first through-hole 230 (a), a second through hole 230 (b), and a third through-hole 230 (c), extending from the first surface 250 to the second surface 255.

The plurality of through-holes 230 may be disposed within the central region 315 in which the substrate 215 occupies.

In various embodiments, the susceptor 210 may further comprise a plurality of lift pins 220, such as a first lift pin 220 (a), a second lift pin 220 (b), and a third lift pin 220 (c). Each lift pin 220 may be disposed within a respective through-hole from the plurality of through-holes. In various embodiments, the lift pin pads 240 may be arranged directly below the lift pins 220 and through-holes 230 to allow the lift pins 220 to make contact with the lift pin pads 240.

In various embodiments, the susceptor 210 may further comprise a plurality of gas channels 305 embedded within the susceptor 210 and configured to flow a gas or vapor. In some cases, the gas channels 305 may extend through the susceptor 210 and connect to a gas line at the second surface 255 of the susceptor 210. In other cases, the gas channels 305 may be configured to join a gas line within the pedestal 280. In various embodiments, the gas channels 305 may be fluidly coupled to the exhaust system 120.

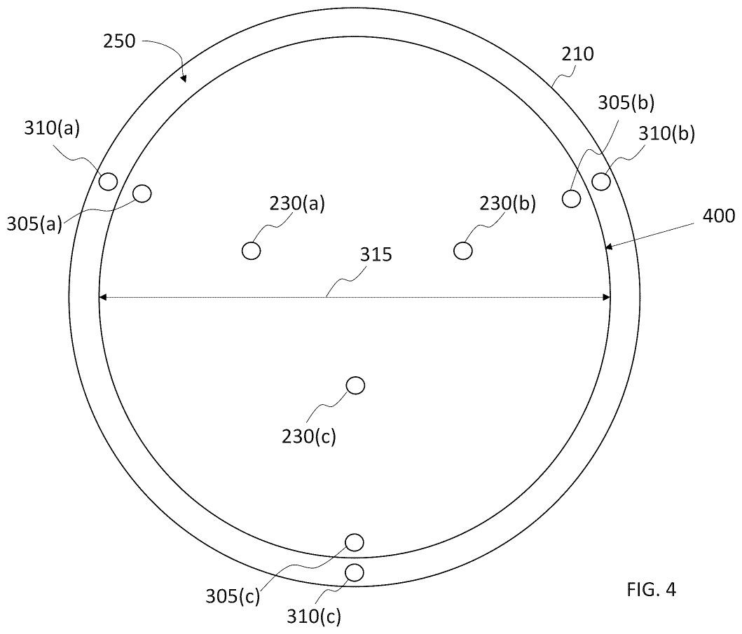

In an exemplary embodiment, and referring to FIGS. 3-4, the susceptor 210 comprises three (3) gas channels, for example, a first gas channel 305 (a), a second gas channel 302 (b), and a third gas channel 305 (c), wherein each gas channel 305 has an opening at the first surface 250 of the susceptor 210. The openings of each gas channel 305 (a), 305 (b), 305 (c), may be arranged within the central region 315 and adjacent to an outer edge 400 of the central region 315. For example, the openings of the gas channels 305 may be 0.5 mm to 10 mm from the outer edge 400. In addition, the openings of each gas channel 305 (a), 305 (b), 305 (c) may be arranged 120 degrees from each other.

In the present embodiment, each gas channel 305 (a), 305 (b), 305 (c) may be fluidly coupled to a respective pressure transducer 300. For example, the first gas channel 305 (a) may be coupled to a first pressure transducer 300 (a) via a first gas line, and the second gas channel 305 (b) may be coupled to a second pressure transducer 300 (b) via a second gas line. The pressure transducers 300 (a), 300 (b) may be arranged downstream from the openings of the gas channels 305. Each pressure transducer 300 may be coupled to the exhaust system 120 and the controller 130. The exhaust system 120 may be coupled downstream from the pressure transducers 300 (a), 300 (b).

In an exemplary embodiment, and referring to FIGS. 5A-5B, the gas channels 305 may be arranged adjacent to the through-hole 230 and lift pin 220. In the present embodiment, the susceptor 210 comprises six (6) gas channels 305, wherein each through-hole 230 has two associated gas channels 305 that are adjacently-located (e.g., within 2-10 mm from the through-hole 230) to the through-hole 230. Alternatively, each through-hole 230 may have only one adjacently-located gas channel 305.

In the present embodiment, each gas channel 305 (or pairs of gas channels) may be fluidly coupled to a respective pressure flow controller 500. For example, each gas channel or pair of gas channels arranged near a single lift pin may be coupled to a single pressure flow controller 500 via a gas line. Each pressure flow controller 500 may be coupled to the inert gas source 105, the exhaust system 120, and the controller 130. The pressure flow controller 500 may be coupled upstream from and inline with the inert gas source 105 and the gas channel 305.

In various embodiments, and referring back to FIGS. 3-4, the susceptor 210 may further comprise a plurality of gas ports 310, such as a first gas port 310 (a), a second gas port 310 (b), and a third gas port 310 (c) configured to allow flow of gas therethrough. In an exemplary embodiment, the gas ports 310 (a), 310 (b), 310 (c) may be disposed on the first surface 250 of the susceptor 210 and arranged 120 degrees from each other. The gas ports 310 may disposed radially outward from the central region 315. In other words, the gas ports 310 are arranged outwards from the outer edge 40 of the central region 315. In addition, each gas port 310 (a), 310 (b), 310 (c) may be directly adjacent to a respective gas channel 305. For example, each gas port may be radially aligned with a respective gas channel opening 305 and radially spaced 1 mm to 10 mm from each other. The gas ports 310 may be fluidly coupled to the inert gas source 105 (FIG. 1).

In operation, and referring to FIGS. 2A and 3-4, the system 100 may be configured to detect a lift pin error. For example, the system 100 may detect a stuck lift pin, wherein the lift pin 220 becomes stuck in the through-hole 230 in the up position, upwards from the through-hole 230 (as illustrated in FIG. 3B).

In an exemplary embodiment, the controller 130 may position the susceptor 210 in the processing position (as illustrated in FIG. 2A). The controller 130 may then initiate gas flow from the inert gas source 105 to the gas ports 310 (a), 310 (b), 310 (c). For example, the controller 130 may activate a valve, upstream from the inert gas source 105 (not shown), to open. As gas starts to flow through the gas ports 310 (a), 310 (b), 310 (c), the exhaust system pump applies a suction force at the openings of the gas channels 305, and the pressure transducers 300 (a), 300 (b) measure the gas flow and/or pressure of the flow. If the substrate 215 is directly contacting the first surface 250 of the susceptor 210, then the gas channel openings 305 will be blocked or otherwise covered up by the substrate 215, which will cause a decrease in measured pressure by the pressure transducer 300. Alternatively, if the substrate 215 is not directly contacting the first surface 250 and the gas channel openings 305 are not blocked by the substrate 215, the pressure through the gas channel 305 will increase. The pressure transducers may transmit the measured pressures/flow rates for each gas channel 305 to the controller 130. The controller 130 may then detect a change in the pressure/flow rate. For example, the controller 130 may detect an increase or a decrease in the pressure/flow rate. If the controller 130 detects an increase in pressure or flow rate, this may indicate a lift pin error, and the controller 130 may generate an error signal in response to the increase in pressure/flow rate. The error signal may stop further processing of the substrate 215 or other functions of the system 100.

Alternatively, the controller 130 may determine that the measured pressure/flow rate is less than a threshold value. If the controller 130 determines that the measured pressure/flow rate is above the threshold value, this may indicate a lift pin error, and the controller 130 may generate an error signal in response to the measured pressure being higher than the threshold pressure value. The error signal may stop further processing of the substrate 215 or other functions of the system 100.

In an alternative operation, and referring to FIGS. 2A and 5A-5B, the system 100 may be configured to detect a lift pin error. For example, the system 100 may detect a stuck lift pin, wherein the lift pin 220 becomes stuck in the through-hole 230 in the up position, upwards from the through-hole 230 (as illustrated in FIG. 3B).

In an exemplary embodiment, the controller 130 may position the susceptor 210 in the processing position (as illustrated in FIG. 2A). The controller 130 may then initiate gas flow from the inert gas source 105 through the pressure flow controller 500 and into the gas channels 305. The pressure flow controller 500 may be set to allow a minimum or target amount of gas to flow through it and into the gas channels 305, and the pressure associated with that set flow rate will be lower than the pressure in the reaction space 235. The gas then flows through the gas channels 305 and towards the first surface 250 of the susceptor 210. In some embodiments, the exhaust system pump 120 may operate to apply a suction force at the same time as the gas is flowing through the pressure flow controller 500 and gas channels 305. If the substrate 215 is directly contacting the first surface 250 of the susceptor 210, then the gas channel openings 305 will be blocked or otherwise covered up by the substrate 215, which will prevent or substantially impede gas flow, and this will cause a decrease in the flow rate or maintain the minimum or target pressure. Alternatively, if the substrate 215 is not directly contacting the first surface 250 and the gas channel openings 305 are not blocked by the substrate 215, the flow rate through the gas channels 305 will increase. The pressure flow controller 500 may transmit the actual flow rates for each gas channel 305 to the controller 130, which may increase or decrease to maintain a particular pressure. The controller 130 may receive the actual flow rates to detect a change in the pressure/flow rate. For example, the controller 130 may detect an increase or a decrease in the pressure/flow rate. If the controller 130 detects an increase in pressure or flow rate from the target pressure/flow rate, this may indicate a lift pin error, and the controller 130 may generate an error signal in response to the increase in pressure/flow rate. The error signal may stop further processing of the substrate 215 or other functions of the system 100.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a susceptor comprising:
a first surface and a second surface that is parallel to the first surface;
a recessed region within the first surface that is sized to accept a wafer;
a first plurality of through-holes extending from the first surface to the second surface and disposed within the recessed region;
a plurality of lift pins disposed within the first plurality of through-holes; and
a plurality of gas channels having an opening at the first surface and within the recessed region;
a plurality of pressure sensors fluidly coupled to the plurality of gas channels; and
a controller in communication with the plurality of sensors and configured to:
detect a change in pressure or flow rate within the plurality of gas channels;
determine a failure of at least one of the plurality of lift pins based on the detected change in pressure or flow rate; and
generate an error signal based on the determined failure.

2. The apparatus according to claim 1, wherein the openings of at least two gas channels from the plurality of gas channels are directly adjacent to each through-hole from the plurality of through-holes.

3. The apparatus according to claim 1, wherein the plurality of gas channels comprises 6 channels.

4. The apparatus according to claim 1, wherein the openings of the plurality of gas channels are disposed 120 degrees from each other.

5. The apparatus according to claim 1, wherein the openings of the plurality of gas channels are arranged adjacent to and radially inward from an outer edge of the recessed region.

6. The apparatus according to claim 1, wherein the plurality of gas channels contains, at most, 3 channels.

7. The apparatus according to claim 1, further comprising a plurality of gas ports disposed at the first surface and coupled to an inert gas supply.

8. The apparatus according to claim 7, wherein the plurality of gas ports are arranged radially outward from the recessed region.

9. The apparatus according to claim 7, wherein the plurality of gas ports are arranged adjacent to the openings of the plurality of gas channels.

10. The apparatus according to claim 7, further comprising a pump coupled to the plurality of gas ports and configured to apply a suction force at the first surface.

11. The apparatus according to claim 1, further comprising a pump coupled to the plurality of gas channels and configured to evacuate air from the plurality of gas channels.

12. The apparatus according to claim 1, wherein determining a failure of at least one lift pin comprises detecting an increase in pressure or flow rate.

13. An apparatus, comprising:
a susceptor comprising:
a first surface and a second surface that is parallel to the first surface;
an interior, circular region on the first surface that is configured to support a wafer;
a first plurality of through-holes extending from the first surface to the second surface and disposed within the interior region;
a plurality of lift pins disposed within the first plurality of through-holes; and
a plurality of gas channels having an opening at the first surface and within the interior region, wherein the plurality of gas channels comprises at least 3 gas channels and wherein the openings of the plurality of gas channels are arranged adjacent to an outer edge of the interior region, and wherein the openings of the plurality of gas channels are disposed 120 degrees from each other;
a plurality of pressure sensors fluidly coupled to the plurality of gas channels;
a controller in communication with the plurality of sensors and configured to:
detect a change in pressure or gas flow rate within at least one channel from the plurality of gas channels;
determine a failure of at least one lift pin from the plurality of lift pins based on the detected change in pressure or flow rate; and
generate an error signal based on the determined failure.

14. The apparatus according to claim 13, further comprising a plurality of gas ports disposed at the first surface and coupled to an inert gas supply, wherein the plurality of gas ports are arranged radially outward from the interior region.

15. The apparatus according to claim 14, wherein the plurality of gas ports are arranged adjacent to the openings of the plurality of gas channels and spaced 120 degrees from each other.

16. The apparatus according to claim 14, further comprising a pump fluidly coupled to the plurality of gas ports and configured to facilitate air flow away from the first surface.

17. The apparatus according to claim 13, wherein determining a failure of at least one lift pin comprises detecting an increase in pressure or gas flow rate.

18. A system, comprising:
a susceptor comprising:
a first surface and a second surface that is parallel to the first surface;
an interior, circular region on the first surface that is configured to support a wafer;
a first plurality of through-holes extending from the first surface to the second surface and disposed within the recessed region;
a plurality of lift pins disposed within the first plurality of through-holes; and
a plurality of gas channels having an opening at the first surface and within the interior region, wherein plurality of gas channels comprises at least 3 channels;
a plurality of pressure sensors fluidly coupled to the plurality of gas channels;
a controller in communication with the plurality of sensors and configured to:
detect a change in pressure or gas flow rate within the plurality of gas channels;
determine a failure of at least one lift pin from the plurality of lift pins based on the detected increase in pressure; and
generate an error signal based on the determined failure; and
a pump coupled to the plurality of gas channels and configured to evacuate air from the plurality of gas channels.

19. The system according to claim 18, wherein each pressure sensor from the plurality of pressure sensors comprises a pressure transducer and the pump is downstream from the plurality of sensors.

20. The system according to claim 18, wherein each pressure sensor from the plurality of pressure sensors comprises a pressure flow controller and each pressure flow controller is fluidly coupled to an inert gas source and configured to receive an inert gas from the inert gas source.
